(19) United States
(12) Patent Application Publication
(10) Pub. No.: US 2026/0164744 A1
(43) Pub. Date: Jun. 11, 2026

(54) SILICIDE FORMATION BY USING VARIATING TEMPERATURE PROCESS

(71) Applicant: Applied Materials, Inc., Santa Clara, CA (US)

(72) Inventors: Ying-Bing JIANG, Woodland, CA (US); Yuxin WANG, San Jose, CA (US); Joung Joo LEE, San Jose, CA (US); Avgerinos V. GELATOS, Scotts Valley, CA (US); Yuan-Chung WEN, Santa Clara, CA (US); Tom H. YU, Campbell, CA (US); Yao XU, Santa Clara, CA (US); Cheng CHENG, Santa Clara, CA (US); Xi CEN, San Jose, CA (US); Kai WU, Palo Alto, CA (US)

(21) Appl. No.: 18/976,241

(22) Filed: Dec. 10, 2024

(51) Int. Cl. H01L 21/285; C23C 16/02; C23C 16/42; C23C 16/56; H01L 21/02; H01L 21/324

(52) U.S. Cl. CPC H10D 64/0112; C23C 16/42; H10P 70/27; H10P 95/90; C23C 16/0227; C23C 16/56

(57) ABSTRACT

A method of forming a metal silicide layer in a semiconductor structure includes performing a silicide deposition process in a processing chamber, in which a metal silicide layer is formed on silicon surfaces within an opening formed in a semiconductor structure, inner surfaces of the opening comprising the silicon surfaces, wherein the silicide deposition process including performing a pre-dose purging process, in which the processing chamber is evacuated at a first pressure, performing a dose process, in which a metal-containing precursor is flowed in the processing chamber at a second pressure that is higher than the first pressure, performing a post-dose purge process, in which the processing chamber is purged at a third pressure that is lower than the second pressure, and performing an anneal process at a fourth pressure that is higher than the second pressure.

### BACKGROUND

### Field

Embodiments described herein generally relate to semiconductor device fabrication, and more particularly, to methods of forming metal silicide.

### Description of the Related Art

The production of silicon integrated circuits has placed difficult demands on fabrication processes to increase the number of devices while decreasing the minimum feature sizes on a chip. These demands have extended to fabrication processes including depositing layers onto difficult topologies while maintaining device reliability. For example, in three dimensional (3D) dynamic random access memory (DRAM) devices or multi-gate metal-oxide-semiconductor field-effect transistors (MOSFETs), such as complementary metal-oxide semiconductor (CMOS) devices, metal silicide (e.g., molybdenum silicide (MoSiₓ), ruthenium silicide (RuₓSi_{y})) is often utilized to lower a contact resistivity in bit line contact (BLC) and storage node contact (SNC). However, metal silicide (e.g., molybdenum silicide (MoSiₓ)) needs to be deposited on sidewalls of deep holes or deep trenches and such deposition has been known to have non uniformity along the depth of the holes/trenches.

Therefore, there is a need for methods and systems that can uniformly form metal silicide along the depth of deep holes or trenches.

### SUMMARY

Embodiments of the present disclosure provide a method of forming a metal silicide layer in a semiconductor structure. The method includes performing a silicide deposition process in a processing chamber, in which a metal silicide layer is formed on silicon surfaces within an opening formed in a semiconductor structure, inner surfaces of the opening comprising the silicon surfaces, wherein the silicide deposition process including performing a pre-dose purging process, in which the processing chamber is evacuated at a first pressure, performing a dose process, in which a metal-containing precursor is flowed in the processing chamber at a second pressure that is higher than the first pressure, performing a post-dose purge process, in which the processing chamber is purged at a third pressure that is lower than the second pressure, and performing an anneal process at a fourth pressure that is higher than the second pressure.

Embodiments of the present disclosure also provide a method of forming a metal silicide layer in a semiconductor structure. The method includes performing a pre-clean process, in which contaminants on silicon surfaces within an opening formed in a semiconductor structure are removed, inner surfaces of the opening comprising the silicon surfaces, performing a silicide deposition process in a processing chamber using a metal-containing precursor while varying chamber pressure, in which a metal silicide layer is formed on the silicon surfaces, performing a cap deposition process, in which a cap layer is deposited on the metal silicide layer, and performing a post annealing process.

Embodiments of the present disclosure further provide a method of forming a metal silicide layer in a semiconductor structure. The method includes performing a pre-clean process, in which contaminants on silicon surfaces within an opening formed in a semiconductor structure are removed, inner surfaces of the opening comprising the silicon surfaces, performing a silicide deposition process in a processing chamber using a metal-containing precursor while varying chamber pressure, in which a metal silicide layer is formed on the silicon surfaces, the silicide deposition process including a pre-dose purging process, in which the processing chamber is evacuated at a first pressure, a dose process, in which the metal-containing precursor is flowed in the processing chamber at a second pressure that is higher than the first pressure, a post-dose purge process, in which the processing chamber is purged at a third pressure that is lower than the second pressure, and an anneal process at a fourth pressure that is higher than the second pressure, performing a cap deposition process, in which a cap layer is deposited on the metal silicide layer, and performing a post annealing process.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic top view of a multi-chamber processing system according to one or more embodiments of the present disclosure.

FIGS. 2 and 2A depict a process flow diagram of a method of forming and post-treating a metal silicide layer in a semiconductor structure according to one or more embodiments of the present disclosure.

FIGS. 3A, 3A′, 3B, 3B′, 3C, and 3C′ are cross-sectional views of a portion of a semiconductor structure corresponding to various states of the method of FIGS. 2 and 2A.

FIG. 4 depicts a chamber pressure variation during the process flow of FIG. 2A.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

The embodiments described herein provide methods for forming metal silicide (e.g., molybdenum silicide (MoSiₓ), titanium silicide (TiSiₓ)) within a deep opening (e.g., a hole or a trench) that can be used to reduce a contact resistance in three dimensional (3D) dynamic random access memory (DRAM) devices or multi-gate metal-oxide-semiconductor field-effect transistors (MOSFETs). By varying and adjusting chamber pressure, the deposition process can be tailored to form a metal silicide layer on inner surfaces of an opening having a high aspect ratio, uniformly along the depth of the opening.

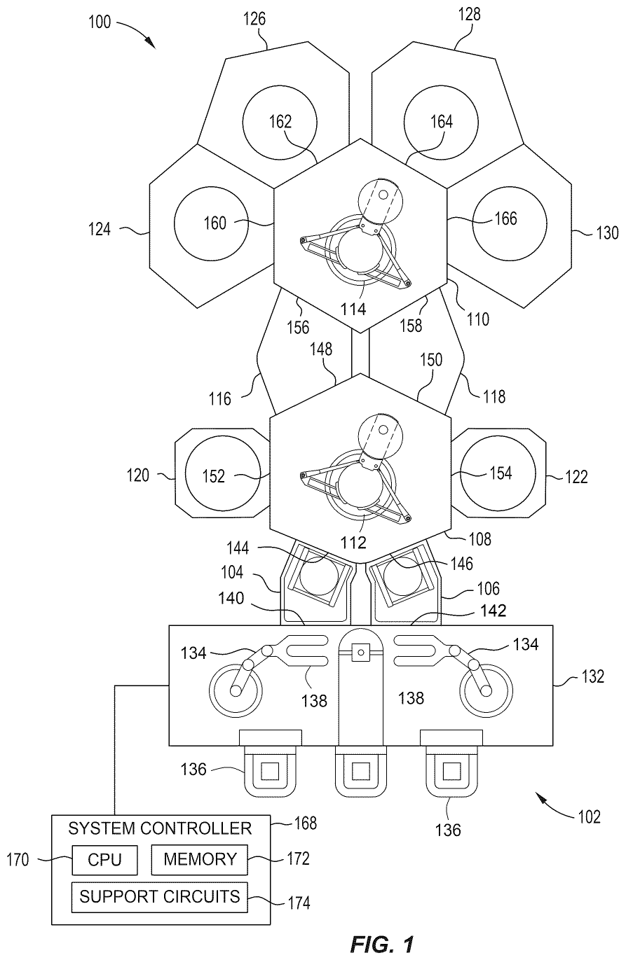

FIG. 1 is a schematic top view of a multi-chamber processing system 100, according to one or more embodiments of the present disclosure. The processing system 100 generally includes a factory interface 102, load lock chambers 104, 106, transfer chambers 108, 110 with respective transfer robots 112, 114, holding chambers 116, 118, and processing chambers 120, 122, 124, 126, 128, 130. As detailed herein, substrates in the processing system 100 can be processed in and transferred between the various chambers without exposing the substrates to an ambient environment exterior to the processing system 100 (e.g., an atmospheric ambient environment such as may be present in a fab). For example, the substrates can be processed in and transferred between the various chambers maintained at a low pressure (e.g., less than or equal to about 300 Torr) or vacuum environment without breaking the low pressure or vacuum environment among various processes performed on the substrates in the processing system 100. Accordingly, the processing system 100 may provide for an integrated solution for some processing of substrates.

Examples of a processing system that may be suitably modified in accordance with the teachings provided herein include the Endura®, Producer® or Centura® integrated processing systems or other suitable processing systems commercially available from Applied Materials, Inc., located in Santa Clara, California. It is contemplated that other processing systems (including those from other manufacturers) may be adapted to benefit from aspects described herein.

In the illustrated example of FIG. 1, the factory interface 102 includes a docking station 132 and factory interface robots 134 to facilitate transfer of substrates. The docking station 132 is adapted to accept one or more front opening unified pods (FOUPs) 136. In some examples, each factory interface robot 134 generally includes a blade 138 disposed on one end of the respective factory interface robot 134 adapted to transfer the substrates from the factory interface 102 to the load lock chambers 104, 106.

The load lock chambers 104, 106 have respective ports 140, 142 coupled to the factory interface 102 and respective ports 144, 146 coupled to the transfer chamber 108. The transfer chamber 108 further has respective ports 148, 150 coupled to the holding chambers 116, 118 and respective ports 152, 154 coupled to processing chambers 120, 122. Similarly, the transfer chamber 110 has respective ports 156, 158 coupled to the holding chambers 116, 118 and respective ports 160, 162, 164, 166 coupled to processing chambers 124, 126, 128, 130. The ports 144, 146, 148, 150, 152, 154, 156, 158, 160, 162, 164, 166 can be, for example, slit valve openings with slit valves for passing substrates therethrough by the transfer robots 112, 114 and for providing a seal between respective chambers to prevent a gas from passing between the respective chambers. Generally, any port is open for transferring a substrate therethrough. Otherwise, the port is closed.

The load lock chambers 104, 106, transfer chambers 108, 110, holding chambers 116, 118, and processing chambers 120, 122, 124, 126, 128, 130 may be fluidly coupled to a gas and pressure control system (not specifically illustrated). The gas and pressure control system can include one or more gas pumps (e.g., turbo pumps, cryo-pumps, roughing pumps), gas sources, various valves, and conduits fluidly coupled to the various chambers. In operation, a factory interface robot 134 transfers a substrate from a FOUP 136 through a port 140 or 142 to a load lock chamber 104 or 106. The gas and pressure control system then pumps down the load lock chamber 104 or 106. The gas and pressure control system further maintains the transfer chambers 108, 110 and holding chambers 116, 118 with an interior low pressure or vacuum environment (which may include an inert gas). Hence, the pumping down of the load lock chamber 104 or 106 facilitates passing the substrate between, for example, the atmospheric environment of the factory interface 102 and the low pressure or vacuum environment of the transfer chamber 108.

With the substrate in the load lock chamber 104 or 106 that has been pumped down, the transfer robot 112 transfers the substrate from the load lock chamber 104 or 106 into the transfer chamber 108 through the port 144 or 146. The transfer robot 112 is then capable of transferring the substrate to and/or between any of the processing chambers 120, 122 through the respective ports 152, 154 for processing and the holding chambers 116, 118 through the respective ports 148, 150 for holding to await further transfer. Similarly, the transfer robot 114 is capable of accessing the substrate in the holding chamber 116 or 118 through the port 156 or 158 and is capable of transferring the substrate to and/or between any of the processing chambers 124, 126, 128, 130 through the respective ports 160, 162, 164, 166 for processing and the holding chambers 116, 118 through the respective ports 156, 158 for holding to await further transfer. The transfer and holding of the substrate within and among the various chambers can be in the low pressure or vacuum environment provided by the gas and pressure control system.

The processing chambers 120, 122, 124, 126, 128, 130 can be any appropriate chamber for processing a substrate. In some examples, the processing chamber 120 can be capable of performing an etch process, the processing chamber 122 can be capable of performing a cleaning process, the processing chamber 124 can be capable of performing a selective removal process, and the processing chambers 126, 128, 130 can be capable of performing respective epitaxial growth processes. The processing chamber 120 may be a Selectra™ Etch chamber available from Applied Materials of Santa Clara, Calif. The processing chamber 122 may be a SiCoNi™ Pre-clean chamber available from Applied Materials of Santa Clara, Calif. The processing chamber 126, 128, or 130 may be a Centura™ Epi chamber available from Applied Materials of Santa Clara, Calif.

A system controller 168 is coupled to the processing system 100 for controlling the processing system 100 or components thereof. For example, the system controller 168 may control the operation of the processing system 100 using a direct control of the chambers 104, 106, 108, 110, 116, 118, 120, 122, 124, 126, 128, 130 of the processing system 100 or by controlling controllers associated with the chambers 104, 106, 108, 110, 116, 118, 120, 122, 124, 126, 128, 130. In operation, the system controller 168 enables data collection and feedback from the respective chambers to coordinate performance of the processing system 100.

The system controller 168 generally includes a central processing unit (CPU) 170, memory 172, and support circuits 174. The CPU 170 may be one of any form of a general purpose processor that can be used in an industrial setting. The memory 172, or non-transitory computer-readable medium, is accessible by the CPU 170 and may be one or more of memory such as random access memory (RAM), read only memory (ROM), floppy disk, hard disk, or any other form of digital storage, local or remote. The support circuits 174 are coupled to the CPU 170 and may comprise cache, clock circuits, input/output subsystems, power supplies, and the like. The various methods disclosed herein may generally be implemented under the control of the CPU 170 by the CPU 170 executing computer instruction code stored in the memory 172 (or in memory of a particular processing chamber) as, for example, a software routine. When the computer instruction code is executed by the CPU 170, the CPU 170 controls the chambers to perform processes in accordance with the various methods.

Other processing systems can be in other configurations. For example, more or fewer processing chambers may be coupled to a transfer apparatus. In the illustrated example, the transfer apparatus includes the transfer chambers 108, 110 and the holding chambers 116, 118. In other examples, more or fewer transfer chambers (e.g., one transfer chamber) and/or more or fewer holding chambers (e.g., no holding chambers) may be implemented as a transfer apparatus in a processing system.

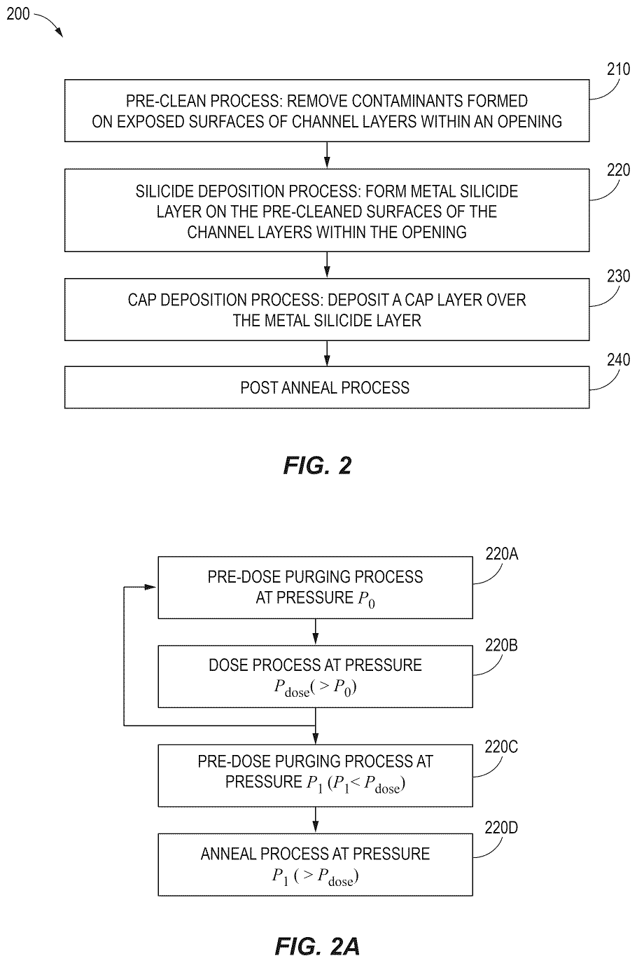

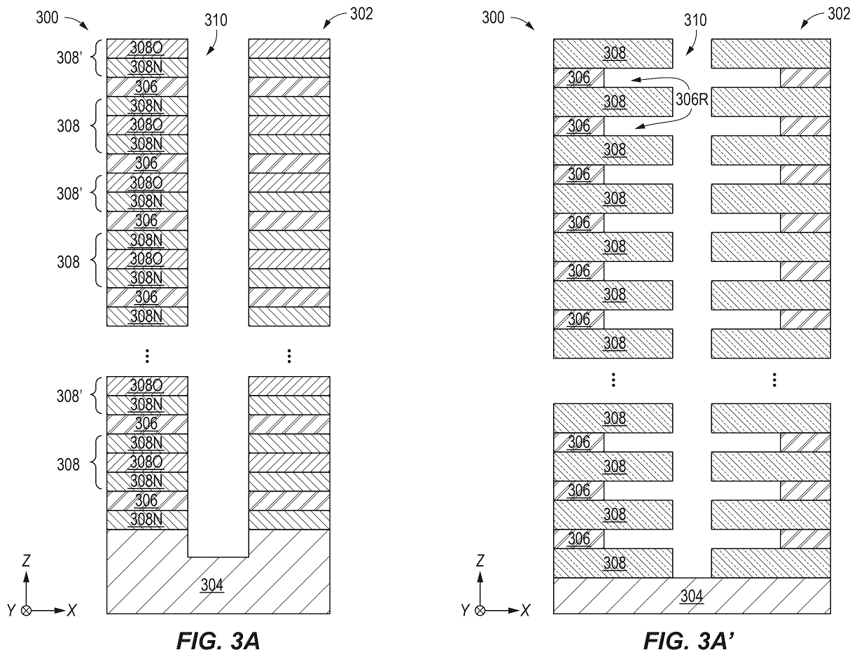

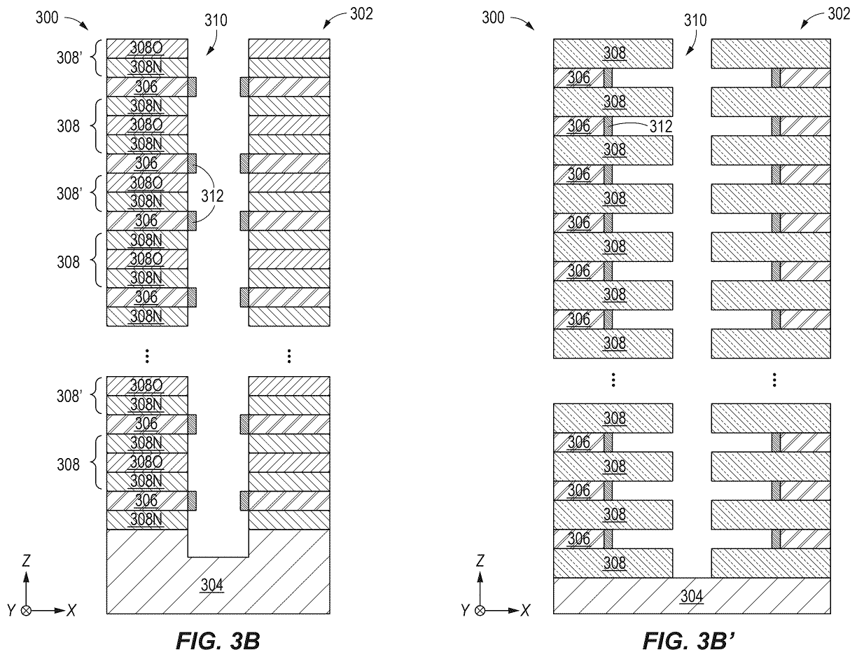

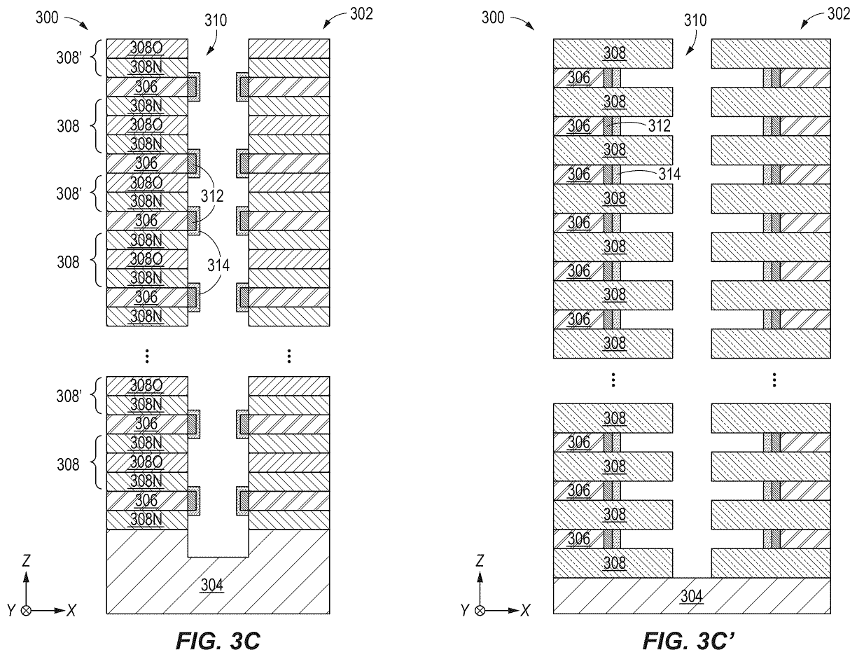

FIGS. 2 and 2A depict a process flow diagram of a method 200 of forming a uniform metal silicide layer in a semiconductor structure 300 according to some embodiments of the present disclosure. FIGS. 3A, 3A′, 3B, 3B′, 3C, and 3C′ are cross-sectional views of a portion of the semiconductor structure 300 corresponding to various states of the method 200. It should be understood that FIGS. 3A, 3A′, 3B, 3B′, 3C, and 3C′ illustrate only partial schematic views of the semiconductor structure 300, and the semiconductor structure 300 may contain any number of transistor sections and additional materials having aspects as illustrated in the figures. It should also be noted that although the method illustrated in FIGS. 2 and 2A is described sequentially, other process sequences that include one or more operations that have been omitted and/or added, and/or has been rearranged in another desirable order, fall within the scope of the embodiments of the disclosure provided herein.

As shown in FIG. 3A, the semiconductor structure 300 includes a layer stack 302 formed on a substrate 304. An opening 310 (e.g., a hole or a trench) is formed through the layer stack 302. The layer stack 302 includes alternating channel layers 306 and dielectric layers 308, 308′ stacked in the Z direction. The channel layers 306 may be formed of silicon(S), each having a thickness of between about 10 nm and about 100 nm, for example, about 50 nm. Each dielectric layer 308 may include a stack of nitride layers 308N formed of silicon nitride (Si₃N₄) and an oxide layer 308O formed of silicon oxide (SiO₂), each having a thickness of between about 10 nm and about 100 nm, for example, about 50 nm. Each dielectric layer 308′ may include a stack of a nitride layer 308N formed of silicon nitride (Si₃N₄) and an oxide layer 308O formed of silicon oxide (SiO₂), each having a thickness of between about 10 nm and about 100 nm, for example, about 50 nm. Thus, inner surfaces of the opening 310 include silicon surfaces (exposed surfaces of the channel layers 306) and dielectric surfaces (exposed surfaces of the dielectric layers 308, 308′). In some embodiments, as shown in FIG. 3A′, the layer stack 302 includes alternating channel layers 306 and dielectric layers 308. Each of the dielectric layers 308 are formed of silicon nitride (Si₃N₄) or silicon oxide (SiO₂) having a thickness of between about 10 nm and about 100 nm, for example, about 50 nm. The channel layers 306 may be recessed from the opening 310, each recess 306R having a depth of between about 10 nm and about 100 nm, for example, about 50 nm. Inner surfaces of the opening 310 include silicon surfaces (exposed surfaces of the channel layers 306) and dielectric surfaces (exposed surfaces of the dielectric layers 308).

The opening 310 has a critical dimension of between about 100 nm and about 150 nm, a depth of between about 4 μm and 8 μm, and thus aspect ratio of between about 1:60 and about 1:80 or higher.

The term “substrate” as used herein refers to a layer of material that serves as a basis for subsequent processing operations and includes a surface to be cleaned. The substrate may be a silicon based material or any suitable insulating materials or conductive materials as needed. The substrate may include a material such as crystalline silicon (e.g., Si<100> or Si<111>), silicon oxide, strained silicon, silicon germanium, doped or undoped polysilicon, doped or undoped silicon wafers and patterned or non-patterned wafers, silicon on insulator (SOI), carbon doped silicon oxides, silicon nitride, doped silicon, germanium, gallium arsenide, glass, or sapphire.

The method 200 begins with a pre-clean process in block 210. The pre-clean process may be performed in a processing chamber, such as the processing chamber 122 shown in FIG. 1.

The pre-clean process is configured to remove contaminants, such as carbon-containing contaminants (e.g., patterning residues), or oxide-containing contaminants (e.g., native oxide layers) formed on exposed surfaces of the channel layers 306 within the opening 310.

The pre-clean process to remove oxide-containing contaminants may include an isotropic etch process, such as a wet etch process using distilled hydrofluoric acid (d-HF) solution, or a dry chemical etch process using ammonia (NH₃), hydrofluoric acid (HF), and gas (e.g., argon (Ar), helium (He)). The etch process is selective for oxide layers, and thus does not readily etch silicon, germanium, or nitride layers regardless of whether the layers are amorphous, crystalline or polycrystalline. Selectivity of the etch process for oxide versus silicon or germanium is at least about 3:1, and usually 5:1 or better, sometimes 10:1. The etch process may be performed at a temperature of between about 35° C. and 90° C. and at a pressure of between about 0.5 Torr and about 2 Torr, for example, about 0.7 Torr.

The pre-clean process may be followed by a pre-clean byproduct sublimation step at a temperature of between about 90° C. and 300° C. with using argon (Ar) or argon (Ar) and hydrogen (H₂) flow.

The pre-clean process to remove carbon-containing contaminants may include an anisotropic remote plasma assisted dry etch process, such as a reactive ion etching (RIE) process, using a plasma formed from a gas including hydrogen (H), argon (Ar), helium (He), or a combination thereof.

In block 220, a silicide deposition process is performed to form a metal silicide layer 312 on the pre-cleaned surfaces of the channel layers 306 within the opening 310, as shown in FIGS. 3B and 3B′. The metal silicide layer 312 may be formed of molybdenum silicide (MoSiₓ, x˜0-3) or titanium silicide (TiSiₓ, x˜0-3), having a thickness of between about 5 Å and about 100 Å, for example, about 50 Å. The silicide deposition process may include chemical vapor deposition (CVD), performed in a processing chamber, such as the processing chamber 126, 128, or 130 shown in FIG. 1.

In CVD deposition at a constant temperature and/or at a constant pressure, the metal deposition is typically not uniform on sidewalls of a high aspect-ratio hole, such as the opening 310, since reactant, such as a molybdenum (Mo)-containing halide precursor or a titanium (Ti)-containing halide precursor, needs to transport to the bottom region of the opening, while by-products need to transport out from the bottom region of the opening. As both transports require extended dose and purge time. Further, both transports generate concentration gradient in the reactant and the by-products along the depth of the opening, resulting differences in the deposition rate along the depth of the opening. Thus, a metal silicide layer 312, if deposited by CVD at a constant temperature and/or at a constant pressure, will not be uniform on inner surfaces of the opening 310.

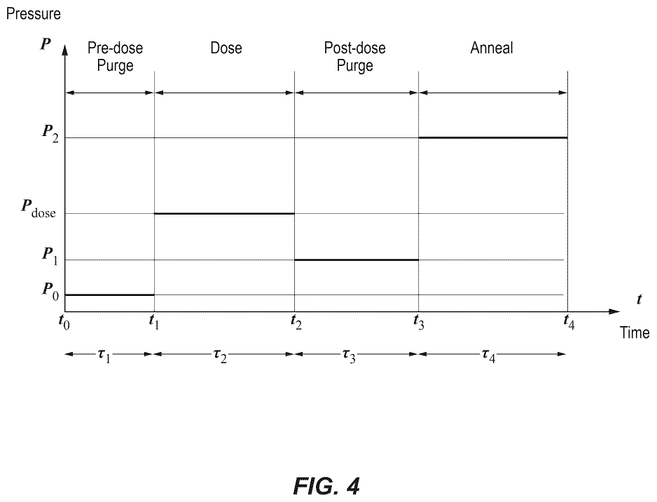

The silicide deposition process includes repeated cycles, within each of which a chamber pressure is varied, as shown in FIG. 4.

Each cycle starts with block 220A, in which a pre-dose purging process is performed to evacuate (empty) the process chamber. The chamber is pumped to a low chamber pressure P₀ of between about 0 Torr and about 10 Torr, for example, about 6 Torr, from time t₀ to time t₁, for a duration τ₁ (e.g., between about 0 seconds and about 60 seconds). The process temperature T₁ may be between about 320° C. and about 500° C.

In block 220B, a dose process is performed to flow a precursor including a metal source (e.g., molybdenum (Mo), titanium (Ti)), such as a molybdenum (Mo)-containing halide precursor (e.g., molybdenum pentachloride (MoCl₅), molybdenum oxytetrachloride (MoOCl₄)) or a titanium (Ti)-containing halide precursor (e.g., titanium tetrachloride (TiCl₄)) in the processing chamber at a slightly higher chamber pressure P_{dose} (e.g., about 10 Torr) that is between about 5 Torr and about 50 Torr higher than the chamber evacuation pressure P₀ (P_{dose}>P₀), from t₁ to time t₂, for a duration τ₂ (e.g., between about 0 seconds and about 60 seconds). In some embodiments, hydrogen (H₂) precursor may be co-flowed. The dose pressure P_{dose} is higher than the chamber evacuation pressure P₀ but still a relatively low pressure during the dose process such that reaction of the precursor with the surfaces of the channel layers 306 within the opening 310 is slow, giving enough time for the precursor to fully diffuse into the opening 310 entirely.

The process temperature T₁ may be maintained during the dose process.

The reaction of a precursor, for example, molybdenum pentachloride (MoCl₅) with the silicon surfaces during the dose process:

$${MoCl}_{5} + {H}_{2} + Si \to {MoSi}_{x} + HCl + {SiH}_{4 - x} {Cl}_{x} + other byproducts ,$$

produces chlorine containing byproducts that may etch the deposited metal silicide layer 312, if left in the processing chamber. Thus, in the subsequent processes, the chlorine containing byproducts are removed from the processing chamber.

In block 220C, a post-dose purge process is performed to purge chlorine containing byproducts from the process chamber at a lower chamber pressure P₁ of between about 0 Torr and about 10 Torr, for example, about 6 Torr. The purge pressure P₁ is lower than the dose pressure P_{dose} (P₁<P_{dose}) to ensure efficient purging. Purge operation can be done using any inert gas such as argon (Ar). In some embodiments, hydrogen (H₂) precursor may be co-flowed.

The process temperature T₁ may be maintained during the purge process.

In block 220D, an anneal process may be performed to further remove chlorine containing byproducts, at a higher chamber pressure P₂ of between about 10 Torr and about 300 Torr, for example, about 100 Torr (P₂>P_{dose}). The post anneal process may include a thermal anneal process in reducing environment that includes hydrogen (H₂), performed in a rapid thermal processing (RTP) chamber, such as the processing chamber 120, 122, 124, 126, 128, or 130 shown in FIG. 1.

The process temperature T₁ may be maintained, or raised by between about 10° C. and about 50° C., during the anneal process. The flow of hydrogen (H₂) may be higher than the flow of hydrogen (H₂) in the dose process in block 220B.

In some embodiments, a CVD soak process is alternatively performed to further remove chlorine containing byproducts in block 220D.

The cycle of blocks 220A, 220B, 220C, and 220D is repeated for between about 50 and about 500 times, until a desired thickness of the metal silicide layer 312 is achieved.

In block 230, a cap deposition process is performed, in which a cap layer 314 is deposited over the metal silicide layer 312, as shown in FIGS. 3C and 3C′. The cap deposition process may include any appropriate deposition process, such as chemical vapor deposition (CVD), or physical vapor deposition (PVD), performed in a processing chamber, such as the processing chamber 126, 128, or 130 shown in FIG. 1. The cap layer 314 may be formed of titanium nitride (TIN), combination of titanium nitride (TiN) and tungsten (W), tungsten (W), or molybdenum (Mo). The cap layer 314 may prevent oxidation of the metal silicide layer 312 during a subsequent anneal process.

In block 240, a post anneal process may be performed to improve properties of the metal silicide layer 312 or the cap layer 314. The post anneal process may include a thermal anneal process in reducing environment that includes silane (SiH₄), carbon oxide (CO), nitrogen (N₂), hydrocarbons (CₓH_{y}) (e.g., methane (CH₄), ethane (C₂H₆), propane (C₃H₈), butane (C₄H₁₀), pentane (C₅H₁₂), hexane (C₆H₁₄)), hydrogen (H₂), ammonia (NH₃), a mixture thereof, and inert gas (e.g., helium (He), argon (Ar)) and other noble gas, performed in a rapid thermal processing (RTP) chamber, such as the processing chamber 120, 122, 124, 126, 128, or 130 shown in FIG. 1. The thermal anneal process may be performed for between about 0 second and about 7200 seconds, at a temperature of between about 500° C. and about 700° C., and at a pressure of between about 0.05 Torr and 300 Torr, repeated for about 1 and about 100 cycles.

The embodiments described herein provide methods for forming metal silicide (e.g., molybdenum silicide (MoSiₓ), titanium silicide (TiSiₓ)) within a deep opening (e.g., a hole or a trench) that can be used to reduce a contact resistance in three dimensional (3D) dynamic random access memory (DRAM) devices or multi-gate metal-oxide-semiconductor field-effect transistors (MOSFETs). By varying and adjusting chamber pressure during a deposition process, a metal silicide layer on inner surfaces of an opening having a high aspect ratio, can be deposited uniformly along the depth of the opening.

While the foregoing is directed to embodiments of the present disclosure, other and further embodiments of the disclosure may be devised without departing from the basic scope thereof, and the scope thereof is determined by the claims that follow.

1. A method of forming a metal silicide layer in a semiconductor structure, comprising:
performing a silicide deposition process in a processing chamber, in which a metal silicide layer is formed on silicon surfaces within an opening formed in a semiconductor structure, inner surfaces of the opening comprising the silicon surfaces, wherein the silicide deposition process comprises:
performing a pre-dose purging process, in which the processing chamber is evacuated at a first pressure;
performing a dose process, in which a metal-containing precursor is flowed in the processing chamber at a second pressure that is higher than the first pressure;
performing a post-dose purge process, in which the processing chamber is purged at a third pressure that is lower than the second pressure; and
performing an anneal process at a fourth pressure that is higher than the second pressure.

2. The method of claim 1, wherein the metal silicide layer comprises molybdenum silicide or titanium silicide having a thickness of between 5 Å and 100 Å.

3. The method of claim 1, wherein the silicide deposition process comprises a vapor deposition (CVD) process.

4. The method of claim 1, further comprising:
prior to the silicide deposition process, performing a pre-cleaning process to remove contaminants on the silicon surfaces within the opening.

5. The method of claim 1, further comprising:
performing a cap deposition process, in which a cap layer is deposited on the metal silicide layer, wherein the cap layer comprises titanium nitride (TiN); and
performing a post annealing process.

6. The method of claim 1, wherein the first pressure is between 0 Torr and 6 Torr, the second pressure is between 5 Torr and 50 Torr, the third pressure is between 0 Torr and 10 Torr, and the fourth pressure is between 10 Torr and 300 Torr.

7. The method of claim 1, wherein the pre-dose purging process, the dose process, and the post-dose purge process are performed at a temperature of between 320° C. and 500° C.

8. A method of forming a metal silicide layer in a semiconductor structure, comprising:
performing a pre-clean process, in which contaminants on silicon surfaces within an opening formed in a semiconductor structure are removed, inner surfaces of the opening comprising the silicon surfaces;
performing a silicide deposition process in a processing chamber using a metal-containing precursor while varying chamber pressure, in which a metal silicide layer is formed on the silicon surfaces;
performing a cap deposition process, in which a cap layer is deposited on the metal silicide layer; and
performing a post annealing process.

9. The method of claim 8, wherein the metal silicide layer comprises molybdenum silicide or titanium silicide having a thickness of between 5 Å and 100 Å.

10. The method of claim 8, wherein the silicide deposition process comprises a vapor deposition (CVD) process.

11. The method of claim 8, wherein the cap layer comprises titanium nitride (TiN).

12. The method of claim 8, wherein the silicide deposition process comprises:
a pre-dose purging process, in which the processing chamber is evacuated at a first pressure;
a dose process, in which the metal-containing precursor is flowed in the processing chamber at a second pressure that is higher than the first pressure;
a post-dose purge process, in which the processing chamber is purged at a third pressure that is lower than the second pressure; and
an anneal process at a fourth pressure that is higher than the second pressure.

13. The method of claim 12, wherein the first pressure is between 0 Torr and 6 Torr, the second pressure is between 5 Torr and 50 Torr, the third pressure is between 0 Torr and 10 Torr, and the fourth pressure is between 10 Torr and 300 Torr.

14. The method of claim 12, wherein the pre-dose purging process, the dose process, and the post-dose purge process are performed at a temperature of between 320° C. and 500° C.

15. A method of forming a metal silicide layer in a semiconductor structure, comprising:
performing a pre-clean process, in which contaminants on silicon surfaces within an opening formed in a semiconductor structure are removed, inner surfaces of the opening comprising the silicon surfaces;
performing a silicide deposition process in a processing chamber using a metal-containing precursor while varying chamber pressure, in which a metal silicide layer is formed on the silicon surfaces, the silicide deposition process comprising:
a pre-dose purging process, in which the processing chamber is evacuated at a first pressure;
a dose process, in which the metal-containing precursor is flowed in the processing chamber at a second pressure that is higher than the first pressure;
a post-dose purge process, in which the processing chamber is purged at a third pressure that is lower than the second pressure; and
an anneal process at a fourth pressure that is higher than the second pressure;
performing a cap deposition process, in which a cap layer is deposited on the metal silicide layer; and
performing a post annealing process.

16. The method of claim 15, wherein the metal silicide layer comprises molybdenum silicide or titanium silicide having a thickness of between 5 Å and 100 Å.

17. The method of claim 15, wherein the silicide deposition process comprises a vapor deposition (CVD) process.

18. The method of claim 15, wherein the cap layer comprises titanium nitride (TiN).

19. The method of claim 15, wherein the first pressure is between 0 Torr and 6 Torr, the second pressure is between 5 Torr and 50 Torr, the third pressure is between 0 Torr and 10 Torr, and the fourth pressure is between 10 Torr and 300 Torr.

20. The method of claim 15, wherein the pre-dose purging process, the dose process, and the post-dose purge process are performed at a temperature of between 320° C. and 500° C.
